(19) United States
(12) Patent Application Publication
(10) Pub. No.: US 2026/0132335 A1
(43) Pub. Date: May 14, 2026

(54) ETCHANT COMPOSITIONS FOR ETCHING SILICON GERMANIUM FILMS AND METHODS OF MANUFACTURING INTEGRATED CIRCUIT DEVICES

(71) Applicant: Samsung Electronics Co., Ltd., Suwon-si (KR)

(72) Inventors: Soojin Kim, Suwon-si (KR); Jaeheon Park, Seongnam-si (KR); Daihyun Kim, Suwon-si (KR); Mihyun Park, Suwon-si (KR); Sangwon Bae, Suwon-si (KR); Jaesung Lee, Seongnam-si (KR)

(73) Assignees: SAMSUNG ELECTRONICS CO., LTD., Suwon-si (KR); SOULBRAIN CO., LTD., Seongnam-si (KR)

(21) Appl. No.: 19/279,567

(22) Filed: Jul. 24, 2025

(30) Foreign Application Priority Data
Nov. 12, 2024 (KR) 10-2024-0160483

(51) Int. Cl. C09K 13/08; H10D 30/01; H10D 62/00; H10D 64/01

(52) U.S. Cl. CPC C09K 13/08; H10D 30/0191; H10D 30/0243; H10D 62/021; H10D 64/017

(57) ABSTRACT

An etchant composition for etching a silicon germanium film is provided, and methods of use thereof, the etchant composition including about 3 wt % to about 90 wt % of an oxidizing agent based on a total amount of an etchant composition, about 0.01 wt % to about 5 wt % of a fluorine compound based on the total amount of the etchant composition, about 0.01 wt % to about 5 wt % of an amine compound based on the total amount of the etchant composition, about 0.01 wt % to about 1 wt % of an inhibitor based on the total amount of the etchant composition, about 1.5 wt % to about 88.5 wt % of an organic solvent based on the total amount of the etchant composition, and a residual amount of water.

### CROSS-REFERENCE TO RELATED APPLICATION

This application is based on and claims priority under 35 U.S.C. § 119 to Korean Patent Application No. 10-2024-0160483, filed on Nov. 12, 2024, in the Korean Intellectual Property Office, the disclosure of which is incorporated by reference herein in its entirety.

### TECHNICAL FIELD

The disclosure relates to an etchant composition and a method of manufacturing an integrated circuit device using the same, and more particularly, to an etchant composition for selectively etching a silicon germanium film and a method of manufacturing an integrated circuit device using the same.

### BACKGROUND

As electronic products are required to be more miniaturized and multifunctional and to have higher performance, higher capacity and higher integration of integrated circuit devices are required. As a result, it is necessary to efficiently design wiring structures in order to achieve high integration while ensuring functions and operating speed required in integrated circuit devices.

### SUMMARY

The inventive concept provides an etchant composition that is used in a method of manufacturing an integrated circuit device having improved performance and reliability.

According to an aspect of the inventive concept, there is provided a method of manufacturing an integrated circuit device having improved performance and reliability.

An etchant composition according to one aspect of the inventive concept is an etchant composition for etching a silicon germanium film, and the etchant composition includes about 3 wt % to about 90 wt % of an oxidizing agent based on the total amount of the etchant composition, about 0.01 wt % to about 5 wt % of a fluorine compound based on the total amount of the etchant composition, about 0.01 wt % to about 5 wt % of an amine compound based on the total amount of the etchant composition, about 0.01 wt % to about 1 wt % of an inhibitor based on the total amount of the etchant composition, about 1.5 wt % to about 88.5 wt % of an organic solvent based on the total amount of the etchant composition, and a residual amount of water.

A method of manufacturing an integrated circuit device according to one aspect of the inventive concept includes forming a laminated structure in which a plurality of silicon films and a plurality of silicon germanium films are alternately laminated one by one on a substrate, etching a portion of the laminated structure to form a recess that exposes the plurality of silicon films and the plurality of silicon germanium films, and selectively removing, by using the etchant composition, and the plurality of silicon germanium films among the plurality of silicon films and the plurality of silicon germanium films, which are exposed by the recess, the etchant composition includes about 3 wt % to about 90 wt % of an oxidizing agent based on the total amount of the etchant composition, about 0.01 wt % to about 5 wt % of a fluorine compound based on the total amount of the etchant composition, about 0.01 wt % to about 5 wt % of an amine compound based on the total amount of the etchant composition, about 0.01 wt % to about 1 wt % of an inhibitor based on the total amount of the etchant composition, about 1.5 wt % to about 88.5 wt % of an organic solvent based on the total amount of the etchant composition; and a residual amount of water.

A method of manufacturing an integrated circuit device according to another aspect of the inventive concept includes forming a laminated structure in which a plurality of silicon films and a plurality of silicon germanium films are alternately laminated one by one on a substrate, forming a dummy gate structure on the laminated structure, etching a portion of the dummy gate structure by using the dummy gate structure as an etching mask to form a source/drain recess that exposes the plurality of silicon films and the plurality of silicon germanium films, selectively removing, by using an etchant composition, a portion of each of the plurality of silicon germanium films among the plurality of silicon films and the plurality of silicon germanium films, which are exposed by the source/drain recess, to thereby form a plurality of inner recesses, forming a plurality of inner spacers within each of the plurality of inner recesses, forming a source/drain region within the source/drain recess, and removing the plurality of silicon germanium films and forming a plurality of gate electrodes. The etchant composition includes about 3 wt % to about 90 wt % of an oxidizing agent based on the total amount of an etchant composition, about 0.01 wt % to about 5 wt % of a fluorine compound based on the total amount of the etchant composition, about 0.01 wt % to about 5 wt % of an amine compound based on the total amount of the etchant composition, about 0.01 wt % to about 1 wt % of an inhibitor based on the total amount of the etchant composition, about 1.5 wt % to about 88.5 wt % of an organic solvent based on the total amount of the etchant composition, and a residual amount of water.

### BRIEF DESCRIPTION OF THE DRAWINGS

Embodiments of the inventive concept will be more clearly understood from the following detailed description taken in conjunction with the accompanying drawings in which:

FIG. 1 is a flowchart for describing a method of manufacturing an integrated circuit device, according to embodiments of the inventive concept;

FIG. 2 to FIG. 11 are cross-sectional views showing diagrams of intermediate stages in which an integrated circuit device is manufactured according to the method of manufacturing an integrated circuit device according to embodiments of the inventive concept;

FIG. 12 is a planar layout diagram for describing an integrated circuit device manufactured according to the method of manufacturing an integrated circuit device according to embodiments of the inventive concept; and

FIG. 13A to FIG. 13C are cross-sectional views for describing an integrated circuit device manufactured according to the method of manufacturing an integrated circuit device according to embodiments of the inventive concept.

### DETAILED DESCRIPTION OF THE EMBODIMENTS

Hereinafter, embodiments according to the inventive concept will be described with reference to the accompanying drawings. Like reference numerals refer to like elements in the drawings, and duplicated descriptions for the same are omitted.

An etchant composition according to embodiments of the inventive concept contains an oxidizing agent, a fluorine compound, an amine compound, an inhibitor, an organic solvent, and water.

In the etchant composition according to embodiments of the inventive concept, the oxidizing agent may be contained in an amount of about 3 wt % to about 90 wt %, or any range therein, for example, about 3 wt % to about 80 wt %, about 10 wt % to about 70 wt %, about 20 wt % to about 50 wt %, based on the total amount of the etchant composition, the fluorine compound may be contained in an amount of about 0.01 wt % to about 5 wt %, or any range therein, for example, about 0.05 wt % to about 3 wt %, about 0.1 wt % to about 3 wt %, about 0.5 wt % to about 2 wt %, based on the total amount of the etchant composition, the amine compound may be contained in an amount of about 0.01 wt % to about 5 wt %, or any range therein, for example, about 0.05 wt % to about 3 wt %, about 0.1 wt % to about 3 wt %, about 0.5 wt % to about 2 wt %, based on the total amount of the etchant composition, the inhibitor may be contained in an amount of about 0.01 wt % to about 1 wt %, or any range therein, for example, about 0.05 wt % to about 0.5 wt %, about 0.1 wt % to about 0.5 wt %, about 0.5 wt % to about 1 wt %, based on the total amount of the etchant composition, and the organic solvent may be contained in an amount of about 1.5 wt % to about 88.5 wt %, or any range therein, for example, about 3 wt % to about 80 wt %, about 10 wt % to about 70 wt %, about 20 wt % to about 50 wt %, based on the total amount of the etchant composition. Water content may be calculated by subtracting the amounts of the oxidizing agent, fluorine compound, amine compound, inhibitor, and organic solvent from the total amount of the etchant composition.

In the etchant composition according to embodiments of the inventive concept, the oxidizing agent may include a peroxyacid compound having 2 to 4 carbon atoms, or a combination thereof. For example, the oxidizing agent may include peracetic acid, perpropionic acid, perbutyric acid, and a combination thereof, but is not limited thereto.

Each of the oxidizing agent and water, which are contained in the etchant composition according to embodiments of the inventive concept, may play a role in oxidizing a Ge element contained in a SiGe film. In embodiments, the Ge element contained in the SiGe film is oxidized in the etchant composition by the oxidizing agent or water, and thus metagermanic acid (H₂GeO₃), which is a soluble substance, may be generated. Since the Ge element is oxidized at an exposed surface of the SiGe film, the Si element having incomplete bonding at the exposed surface of the SiGe film may be removed through oxidation by the oxidizing agent contained in the etchant composition and etching by the fluorine compound contained in the etchant composition.

In particular, since the etchant composition according to embodiments of the inventive concept contains an oxidizing agent including a peroxyacid compound having 2 to 4 carbon atoms, or a combination thereof, an oxidation rate of the SiGe film may increase, which may reduce the dependence of the Ge concentration in the SiGe film. Therefore, using the etchant composition according to embodiments provided herein, an SiGe film having a low Ge concentration may be removed. Therefore, the SiGe film may be removed even when the Ge concentration of the SiGe film is lowered in a portion adjacent to a boundary between the SiGe film and the Si film. For example, a length of a SiGe tail may be reduced.

That is, since the etchant composition according to embodiments of the inventive concept contains an oxidizing agent including a peroxyacid compound having 2 to 4 carbon atoms, or a combination thereof, performance and reliability of the method of manufacturing an integrated circuit device may be improved in the method using the above-described etchant composition.

That is, since the etchant composition according to embodiments of the inventive concept contains an oxidizing agent including a peroxyacid compound having 2 to 4 carbon atoms, or a combination thereof, performance and reliability of an integrated circuit device manufactured according to the method of manufacturing an integrated circuit device may be improved, the method using the above-described etchant composition.

In the etchant composition according to embodiments of the inventive concept, the organic solvent may include a carboxylic acid compound having 2 to 4 carbon atoms, or a combination thereof. In embodiments, the organic solvent may include acetic acid, propionic acid, butyric acid, and a combination thereof.

In particular, since the etchant composition according to embodiments of the inventive concept contains an organic solvent including a carboxylic acid compound having 2 to 4 carbon atoms, or a combination thereof, solubility of etching by-products is improved, and thus etching performance and reliability of the SiGe film in a narrow pattern may be improved. In some embodiments, a length of a SiGe tail may be reduced.

That is, since the etchant composition according to embodiments of the inventive concept contains the organic solvent including a carboxylic acid compound having 2 to 4 carbon atoms, or a combination thereof, performance and reliability of the method of manufacturing an integrated circuit device may be improved, the method using the above-described etchant composition.

That is, since the etchant composition according to embodiments of the inventive concept contains the organic solvent including a carboxylic acid compound having 2 to 4 carbon atoms, or a combination thereof, performance and reliability of an integrated circuit device manufactured according to the method of manufacturing an integrated circuit device may be improved, the method using the above-described etchant composition.

In the etchant composition according to embodiments of the inventive concept, the organic solvent may include the same number of carbon atoms as the number of carbon atoms of the oxidizing agent. In embodiments, an equilibrium state of the etchant composition may be maintained when the oxidizing agent contains the same number of carbon atoms as the organic solvent, and thus an etching rate of the SiGe film may be relatively maintained constant.

In embodiments, when the oxidizing agent includes peracetic acid, the organic solvent may include acetic acid. In embodiments, when the oxidizing agent includes perpropionic acid, the organic solvent may include propionic acid. In embodiments, when the oxidizing agent includes perbutyric acid, the organic solvent may include butyric acid.

Since the etchant composition according to embodiments of the inventive concept contains an oxidizing agent and an organic solvent, which have the same number of carbon atoms, consistency of the etching rate of the SiGe film may be improved.

That is, since the etchant composition according to embodiments of the inventive concept contains an oxidizing agent and an organic solvent, which have the same number of carbon atoms, the reliability of the method of manufacturing an integrated circuit device may be improved, the method using the above-described etchant composition. Since the etchant composition according to embodiments of the inventive concept contains an oxidizing agent and an organic solvent, which have the same number of carbon atoms, the performance and reliability of the integrated circuit device manufactured by the method of manufacturing an integrated circuit device may be improved, the method using the above-described etchant composition.

For example, in order to etch a SiGe film in a simulated pattern in which a SiGe film and a Si film were repeatedly laminated, Experimental Examples 1 to 3 of etchant compositions according to example embodiments of the inventive concept were used. Compositions thereof and results are as follows.
Experimental Example 1: Peracetic acid (oxidizing agent)/acetic acid (organic solvent)
Experimental Example 2: Perpropionic acid (oxidizing agent)/propionic acid (organic solvent)
Experimental Example 3: Butyric acid (oxidizing agent)/perbutyric acid (organic solvent)

In Experimental Example 1 described above, it was confirmed that a difference in degree of etching between an uppermost SiGe film having a largest pattern size and a lowermost SiGe film having a smallest pattern size was 4.17 nm. In Experimental Example 3 described above, it was confirmed that a difference in degree of etching between an uppermost SiGe film having a largest pattern size and a lowermost SiGe film having a smallest pattern size was 2.9 nm.

In Experimental Example 1 described above, it was confirmed that a length of a SiGe tail was 2.77 nm. In Experimental Example 2 described above, it was confirmed that a length of a SiGe tail was 2.46 nm. In Experimental Example 3 described above, it was confirmed that a length of a SiGe tail was 2.15 nm.

In the etchant composition according to embodiments of the inventive concept, the combined content of the oxidizing agent and the organic solvent may be about 91.5 wt % based on the total amount of the etchant composition. The oxidizing agent may be contained in an amount of about 3 wt % to about 90 wt %, or any range therein, based on the total amount of the etchant composition, and an amount of the organic solvent may be calculated by subtracting the weight percentage of the oxidizing agent from about 91.5 wt %.

The results obtained by checking an etching rate (Å/min) of each of the SiGe film, the Si film, and the oxide film, as well as an etching selectivity of the SiGe film against the Si film and an etching selectivity of the SiGe film against the oxide film, by changing a weight ratio between the oxidizing agent and the organic solvent, are as shown in Table 1 below.

TABLE 1

| | | Etch Rate (Å/min) | | | | |
|---|---|---|---|---|---|---|
| Composition (wt %) | | | | ALD | Selectivity | |
| Oxidant | Solvent | SiGe | Poly Si | oxide | SiGe/Si | SiGe/Ox |
| 5 | 86.5 | 165.7 | 3.9 | 77 | 42.5 | 2.2 |
| 10 | 81.5 | 137.8 | 4.1 | 30.5 | 34 | 4.5 |
| 15 | 76.5 | 107 | 4.5 | 14.6 | 23.5 | 7.3 |
| 22.5 | 69 | 98.6 | 4.6 | 13.8 | 21.6 | 7.1 |
| 30 | 61.5 | 87 | 5.7 | 10.6 | 15.3 | 8.2 |
| 37.5 | 54 | 79.4 | 5.6 | 10.8 | 14.3 | 7.3 |
| 45 | 46.5 | 73.9 | 5.3 | 9.8 | 14.1 | 7.6 |
| 60 | 31.5 | 61.8 | 4.8 | 9.6 | 12.8 | 6.4 |
| 90 | 1.5 | 50 | 4.2 | 8.1 | 11.9 | 6.2 |

With reference to Table 1 described above, the etching amount of the SiGe film and the etching selectivity of the SiGe film against the Si film may be controlled according to a weight ratio of the oxidizing agent contained in the etchant composition that is provided according to embodiments of the inventive concept.

In the etchant composition according to embodiments of the inventive concept, the fluorine compound may include hydrofluoric acid (HF), lithium fluoride (LiF), sodium fluoride (NaF), potassium fluoride (KF), aluminum fluoride (AlF₃), lithium borofluoride (LiBF₄), calcium fluoride (CaF₂), sodium bifluoride (NaHF₂), ammonium fluoride (NH₄F), ammonium difluoride (NH₄HF₂), tetramethylammonium fluoride ((CH₃)₄NF), potassium bifluoride (KHF₂), fluoroboric acid (HBF₄), ammonium borofluoride (NH₄BF₄), potassium borofluoride (KBF₄), hexafluorosilicic acid (H₂SiF₆), or a combination thereof.

In the etchant composition according to embodiments of the inventive concept, the amine compound may include an aliphatic diamine compound having 1 to 12 carbon atoms, a methylated aliphatic diamine compound having 1 to 12 carbon atoms, or a combination thereof. In embodiments, the amine compound may include an aliphatic diamine compound having 3 to 8 carbon atoms, a methylated aliphatic diamine compound having 3 to 8 carbon atoms, or a combination thereof.

The amine compound contained in the etchant composition may act as an etch booster that promotes the etching of the resultant product of oxidation (Ge oxide) of the Ge element oxidized by the oxidizing agent or water and the resultant product of oxidation (Si oxide) of Si oxidized by the oxidizing agent. Therefore, the amine compound may increase the etching selectivity of a plurality of SiGe films with respect to a plurality of Si films. The amine compound may be adsorbed to the Ge oxide and the Si oxide, which are formed during the etching process by the etchant composition. The Ge oxide and the Si oxide, to which the amine compound has been adsorbed, may easily and rapidly react with a fluorine ion of the fluorine compound contained in the etchant composition. Therefore, the amine compound may help removal of the Ge oxide and the Si oxide, which are formed during the etching process by the etchant composition.

The results which have been obtained by checking an etching rate (Å/min) of each of the Si film and the SiGe film, and the etching selectivity of the SiGe film against the Si film, by using etchant composition containing amine compounds obtained by varying the number of carbon atoms and changing weight ratios, are as shown in Table 2 below.

TABLE 2

| | |
|---|---|
| Number of | Etching rate(Å/min) |

| carbon atoms | wt % | SiGe | Poly Si | Selectivity |
|---|---|---|---|---|
| w/o | 0 | 96.4 | 6.1 | 15.8 |
| C2 | 0.04 | 122.9 | 4.9 | 25.1 |
| | 0.08 | 151 | 4.4 | 34.3 |
| | 0.098 | 167.6 | 4.7 | 35.7 |
| C3 | 0.05 | 124.6 | 4.4 | 28.3 |
| | 0.121 | 203.7 | 6 | 34.0 |
| C4 | 0.121 | 152.8 | 4.8 | 31.8 |
| | 0.144 | 179.3 | 5.4 | 33.2 |
| C5 | 0.121 | 123.1 | 5.2 | 23.7 |
| | 0.19 | 162 | 5.2 | 31.2 |
| C6 | 0.08 | 106.6 | 6.1 | 17.5 |
| | 0.121 | 110.4 | 4.5 | 24.5 |
| | 0.19 | 148.7 | 5 | 29.7 |
| | 0.31 | 254.5 | 10.4 | 24.5 |
| | 0.63 | 194.3 | 13 | 14.9 |
| C8 | 0.121 | 98.6 | 4.6 | 21.4 |
| | 0.235 | 114.1 | 5.5 | 20.7 |
| C10 | 0.121 | 81.5 | 4.7 | 17.3 |
| | 0.281 | 111.9 | 5.6 | 20.0 |
| C12 | 0.121 | 89.5 | 5 | 17.9 |
| | 0.327 | 108.9 | 5.7 | 19.1 |

In the etchant composition according to embodiments of the inventive concept, the inhibitor may include sulfuric acid or methanesulfonic acid.

The results obtained by checking an etching rate (Å/min) of each of the Si film and the SiGe film, and an etching selectivity of the SiGe film against the Si film, by using etchant compositions containing inhibitors obtained by varying weight ratios different from each other, are as shown in Table 3 below.

TABLE 3

| | Etching | Etching | |
|---|---|---|---|
| | rate(Å/min) | rate(Å/min) | |
| wt % | SiGe | Poly Si | Selectivity |
| 0 | 190.7 | 6.3 | 30.3 |
| 0.5 | 168.5 | 5.8 | 29.1 |
| 1 | 157.9 | 6.5 | 24.3 |
| 3 | 168.8 | 7.3 | 23.1 |
| 5 | 176.3 | 7.9 | 22.3 |

With reference to Table 3 above, it can be confirmed that since the above-described etchant composition contains an inhibitor up to 1 wt % (for example, about 0.5 wt % or about 1 wt %) based on the total amount of the above-described etchant composition, the etching rate of the SiGe film decreases as compared with a case where the etchant composition contains no inhibitor. In this case, it can be also confirmed that the etching selectivity of the SiGe film against the Si film is maintained at a certain level or higher. On the other hand, when the weight ratio of the inhibitor exceeds 1 wt % (for example, about 3 wt % or about 5 wt %) based on the total amount of the etchant composition, it can be confirmed that the etching rate of the SiGe film increases again.

The inhibitor contained in the etchant composition may reduce the etching rate of the SiGe film. In embodiments, since the above-described etchant composition contains an inhibitor, the overall etching rate by the above-described etchant composition may be reduced, which may improve controllability during the etching process of the SiGe film. In embodiments, since the above-described etchant composition contains an inhibitor, the overall etching rate by the above-described etchant composition may be reduced, which may improve dispersity during the etching process of the SiGe film.

Specifically, when the etching rate by the etchant composition according to a comparative example, which is not according to the inventive concept, is too fast, there may be difficulty in controlling the etching process. That is, during the etching process of a SiGe film with an etchant composition according to the comparative example, which is not according to the inventive concept, there may be difficulty in managing the dispersity of the etching results.

That is, the etchant composition according to embodiments of the inventive concept contains an inhibitor, and thus the reliability of the method of manufacturing an integrated circuit device may be improved, the method using the above-described etchant composition. Since the etchant composition according to embodiments of the inventive concept contains an inhibitor, the performance and reliability of the integrated circuit device manufactured by the method of manufacturing an integrated circuit device may be improved, the method using the above-described etchant composition.

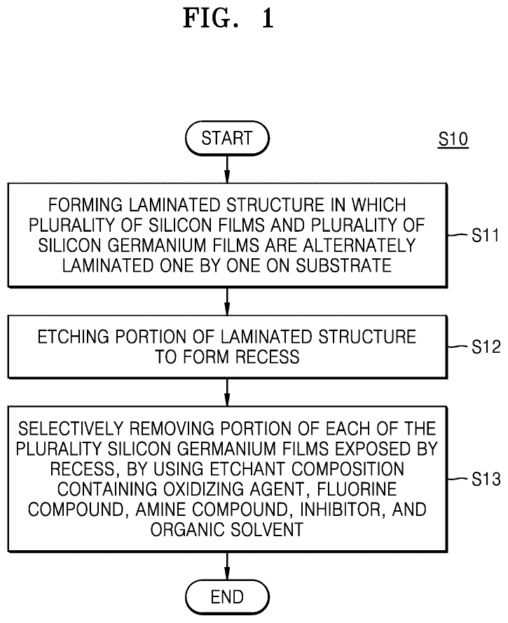

In a structure in which a Si film and a SiGe film are exposed at the same time by the etchant composition according to embodiments of the inventive concept, consistency of the etching rate may be improved, a SiGe tail phenomenon may be improved, and controllability may be improved during the etching process of the SiGe film among the Si film and the SiGe film. In particular, in an exemplary method (S10, see FIG. 1) of manufacturing an integrated circuit device including a field effect transistor, which has a gate-all-around structure including an active region in a nanowire or nanosheet shape and including a gate covering the active region, the consistency of the etching rate may be improved, the SiGe tail phenomenon may be improved, and the controllability may be improved during an etching process of the SiGe film among the Si film and the SiGe film. The details thereof will be described later with reference to FIG. 1 to FIG. 11.

FIG. 1 is a flowchart for describing a method (S10) of manufacturing an integrated circuit device, according to embodiments of the inventive concept.

Referring to FIG. 1, forming (S11) a laminated structure in which a plurality of Si films and a plurality of SiGe films are alternately laminated one by one may be carried out on a substrate.

The substrate may include a semiconductor substrate. In embodiments, the semiconductor substrate may include: an elemental semiconductor such as Si, and Ge; or a compound semiconductor such as silicon carbide (SiC), gallium arsenide (GaAs), indium arsenide (InAs), and indium phosphide (InP), but is not limited thereto.

An epitaxial growth process may be carried out to form the laminated structure. In the laminated structure, each of the plurality of Si films may include a single crystal Si film. In the above-described laminated structure, each of the plurality of SiGe films may have a Ge content ratio selected within a range of 50% by atom or less.

Referring to FIG. 1 continuously, etching a portion of the laminated structure to form a recess (S12) may be carried out. By the recess, the plurality of Si films and the plurality of SiGe films may be exposed.

Referring to FIG. 1 continuously, selectively removing (S13) a portion of each of the plurality of Si films and the plurality of SiGe films exposed by the recess using an etchant composition may be carried out. Specific compositions of the etchant composition are the same as described above for the etchant composition according to embodiments according to the inventive concept.

In embodiments, in the above-described etchant composition, the oxidizing agent may include a peroxyacid compound having 2 to 4 carbon atoms, or a combination thereof, the fluorine compound may include hydrofluoric acid (HF), an aliphatic diamine compound having 1 to 12 carbon atoms, a methylated aliphatic diamine compound having 1 to 12 carbon atoms, or a combination thereof, the inhibitor may be sulfuric acid or methanesulfonic acid such that the content thereof is about 0.01 wt % to about 1 wt %, or any range therein, based on the total amount of the above-described etchant composition, and the organic solvent may include a carboxylic acid compound having 2 to 4 carbon atoms, or a combination thereof. In the etchant composition, the number of carbon atoms of the oxidizing agent may be the same as the number of carbon atoms of the organic solvent.

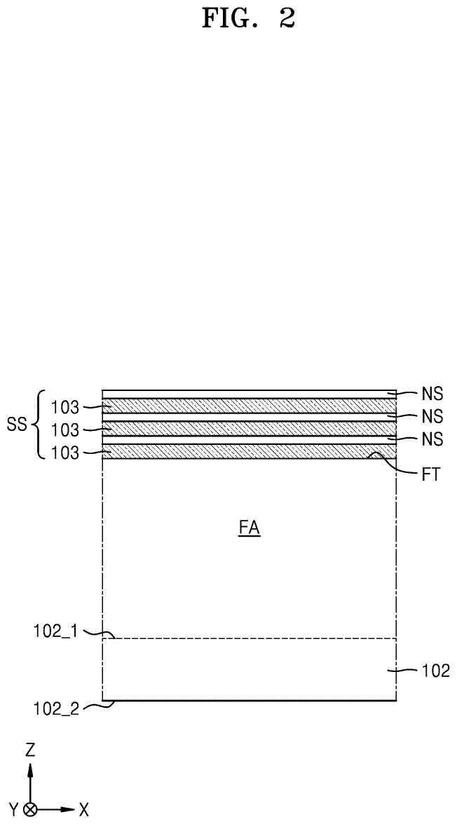

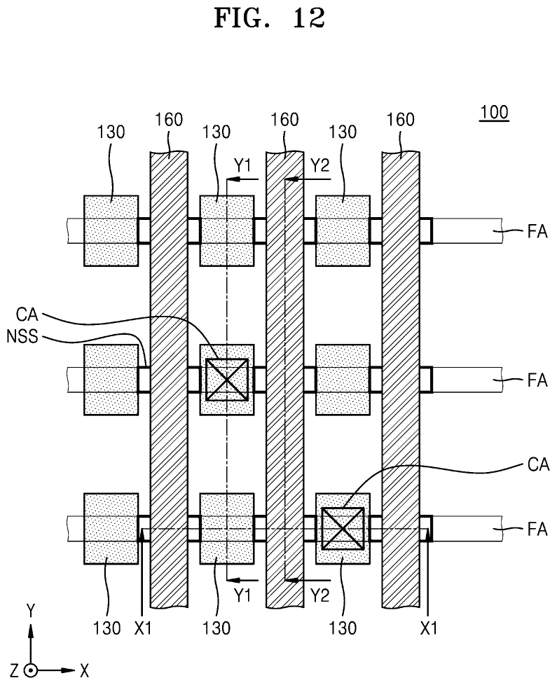

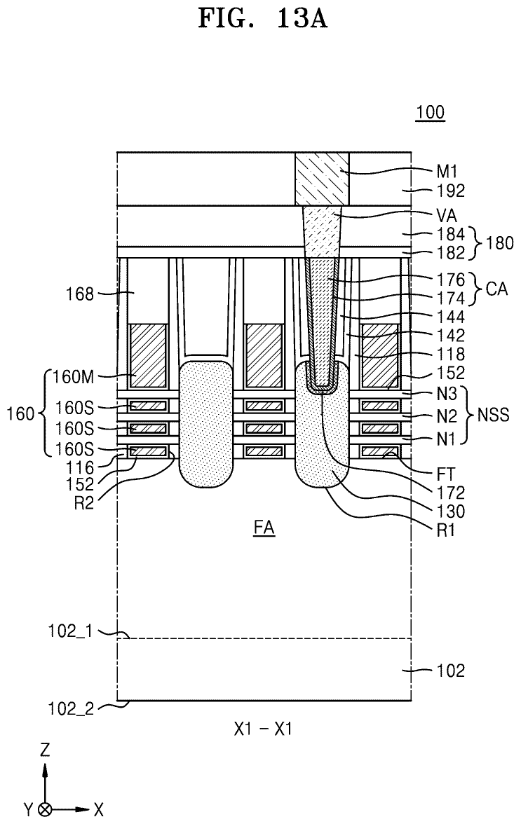

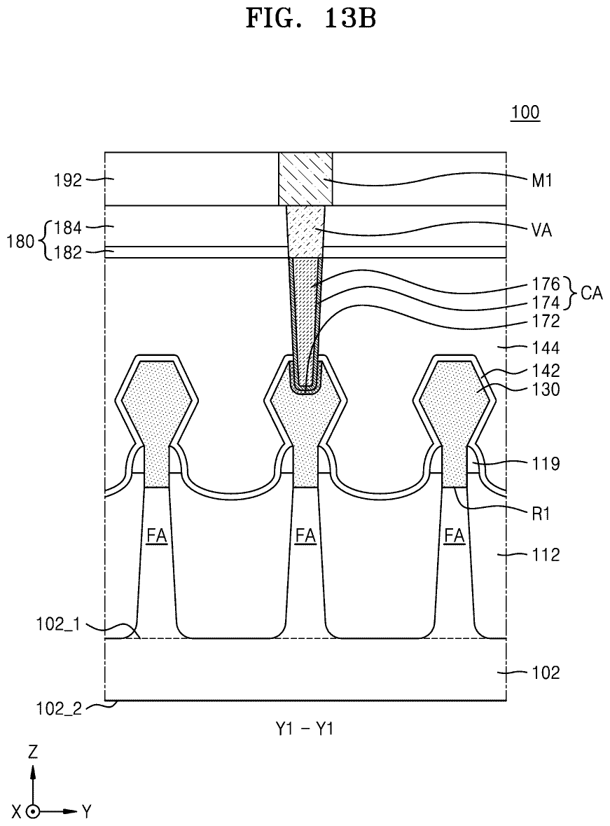

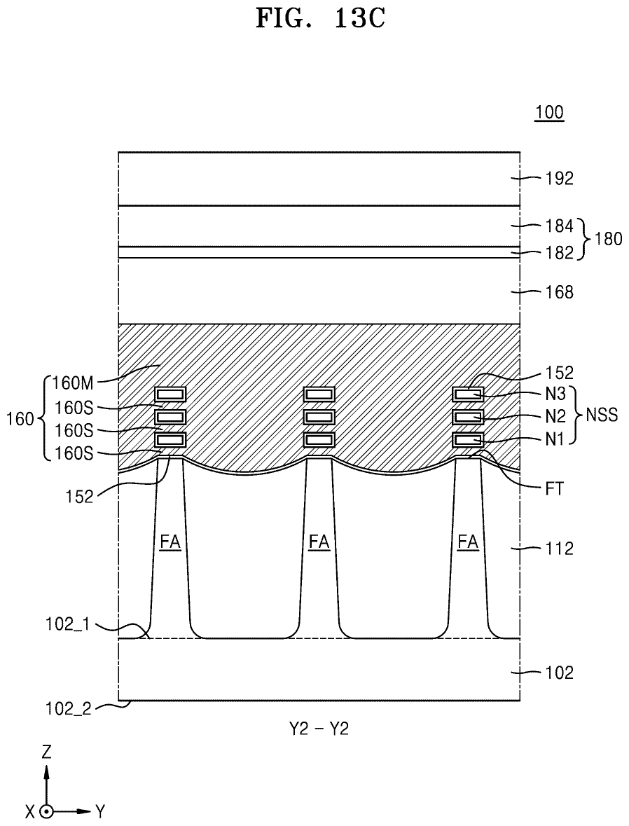

FIG. 2 to FIG. 11 are cross-sectional views showing diagrams of intermediate stages in which the integrated circuit device 100 (see FIG. 12 and FIG. 13A to FIG. 13C) is manufactured according to the method of manufacturing an integrated circuit device according to embodiments of the inventive concept. Specifically, FIG. 2 to FIG. 11 are cross-sectional views corresponding to a cross-section taken along line X1-X1 in FIG. 12.

Referring to FIG. 2, a laminated structure SS in which a plurality of sacrificial semiconductor layers 103 and a plurality of nanosheet semiconductor layers NS are alternately laminated in layers one by one on a substrate 102 may be formed. In some embodiments, the plurality of sacrificial semiconductor layers 103 and the plurality of nanosheet semiconductor layers NS may include semiconductor materials having different etching selectivity from each other.

The substrate 102 may include: an elemental semiconductor such as Si or Ge; or a compound semiconductor such as SiGe, SiC, GaAs, InAs, InGaAs, or InP. The substrate 102 may comprise a first surface 102_1 and a second surface 102_2.

Each of the plurality of sacrificial semiconductor layers 103 and the plurality of nanosheet semiconductor layers NS, which constitute the laminated structure SS, may be formed by an epitaxial growth process. In embodiments, the plurality of nanosheet semiconductor layers NS may include a single crystal Si film, and the plurality of sacrificial semiconductor layers 103 may include a SiGe film.

Thereafter, a portion of the sacrificial semiconductor layer 103, the plurality of nanosheet semiconductor layers NS, and a portion of the substrate 102 are etched, and thus a plurality of fin-shaped active regions FA that extend in a first horizontal direction (X direction) on the substrate 102 may be formed. Therefore, the first surface 102_1 of the substrate 102 may be formed and the plurality of fin-shaped active regions FA may be arranged on the first surface 102_1. The laminated structure SS of the plurality of sacrificial semiconductor layers 103 and the plurality of nanosheet semiconductor layers NS may remain on a top surface FT of each fin of the plurality of fin-shaped active regions FA.

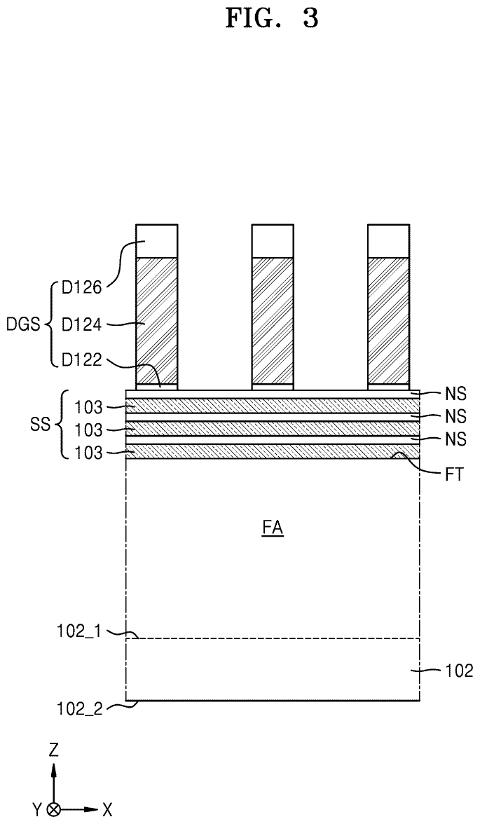

Referring to FIG. 3, a plurality of dummy gate structures DGS may be formed in the laminated structure SS.

Each of the plurality of dummy gate structures DGS may be formed to extend in a second horizontal direction (Y direction). Each of the plurality of dummy gate structures DGS may have a structure in which an oxide film D122, a dummy gate layer D124, and a capping layer D126 are sequentially laminated. In some embodiments, the dummy gate layer D124 may include polysilicon, and the capping layer D126 may include a silicon nitride film.

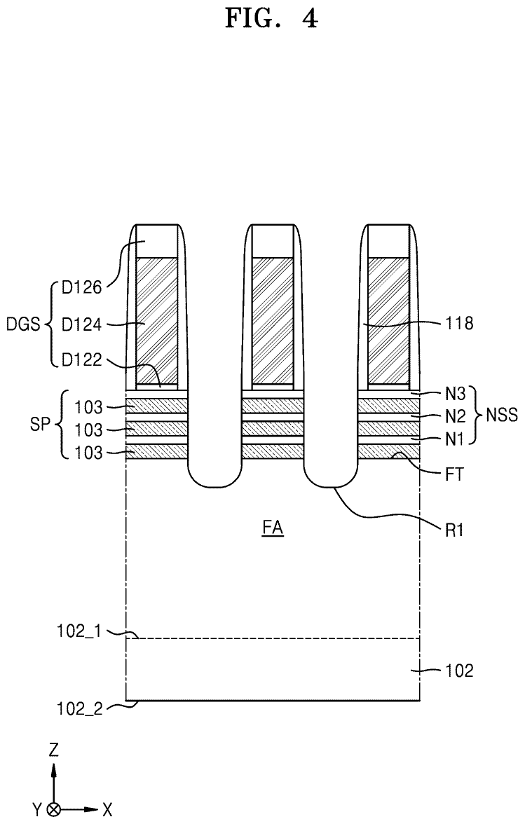

Referring to FIG. 4, after forming a plurality of outer insulating spacers 118 that cover both side walls of each of the plurality of dummy gate structures DGS, a portion of the plurality of sacrificial semiconductor layers 103 and a portion of the plurality of nanosheet semiconductor layers NS may be etched using the plurality of dummy gate structures DGS and the plurality of outer insulating spacers 118 as etching masks. Therefore, the plurality of nanosheet semiconductor layers NS may be each divided into a plurality of nanosheet stacks NSS including a first nanosheet N1, a second nanosheet N2, and a third nanosheet N3.

By the etching process, a laminated pattern SP including the plurality of sacrificial semiconductor layers 103 and a plurality of nanosheets N1, N2, and N3 may be formed.

By the etching process, a plurality of first recesses R1 that expose the side wall of the laminated pattern SP may be formed. In order to form the plurality of first recesses R1, etching may be carried out using dry etching, wet etching, or a combination thereof.

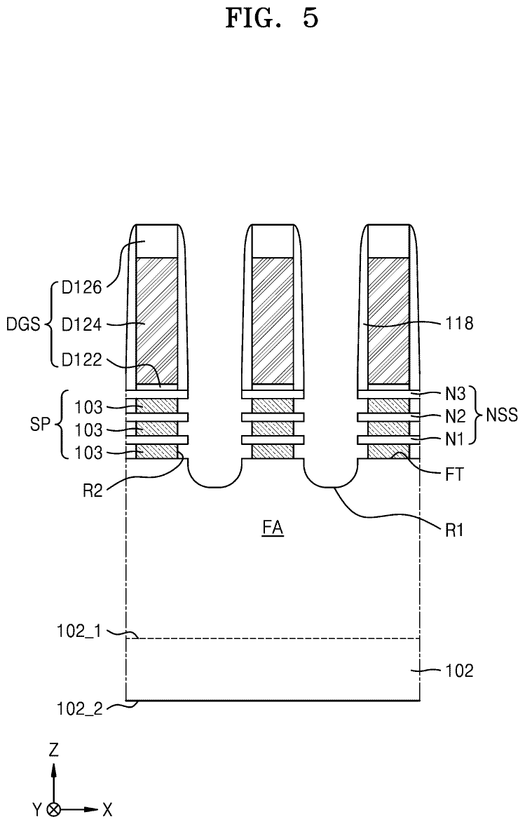

Referring to FIG. 5, a portion of each of the plurality of sacrificial semiconductor layers 103 of the laminated pattern SP, exposed by each of the plurality of first recesses R1, may be removed to form a plurality of second recesses R2.

In order to form the plurality of second recesses R2, an etchant composition may be applied to the laminated pattern SP through the plurality of first recesses R1. Specific compositions of the above-described etchant composition is the same as described above for the etchant composition according to embodiments according to the inventive concept. By applying the etchant composition to the laminated pattern SP, a portion of each of the plurality of sacrificial semiconductor layers 103 among the plurality of nanosheets N1, N2, and N3 may be selectively removed.

In embodiments, in the etchant composition used for selective removing of a portion of each of the plurality of sacrificial semiconductor layers 103, the oxidizing agent may include a peroxyacid compound having 2 to 4 carbon atoms, or a combination thereof, the fluorine compound may include hydrofluoric acid (HF), the amine compound may include an aliphatic diamine compound having 1 to 12 carbon atoms, a methylated aliphatic diamine compound having 1 to 12 carbon atoms, or a combination thereof, the inhibitor may include sulfuric acid or methanesulfonic acid, and the organic solvent may include a carboxylic acid compound having 2 to 4 carbon atoms, or a combination thereof. In the etchant composition, the number of carbon atoms of the oxidizing agent may be the same as the number of carbon atoms of the organic solvent.

In the selective removing of the plurality of SiGe films using the etchant composition according to the inventive concept, consistency of the etching rate may be improved, the SiGe tail phenomenon may be improved, and controllability may be improved.

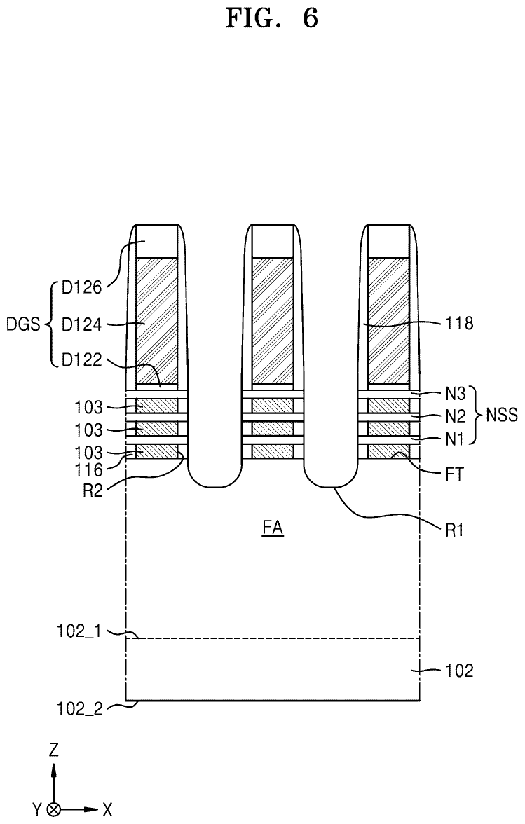

Referring to FIG. 6, a plurality of inner insulating spacers 116 may be formed within the plurality of second recesses R2. The plurality of inner insulating spacers 116 may contain a silicon nitride.

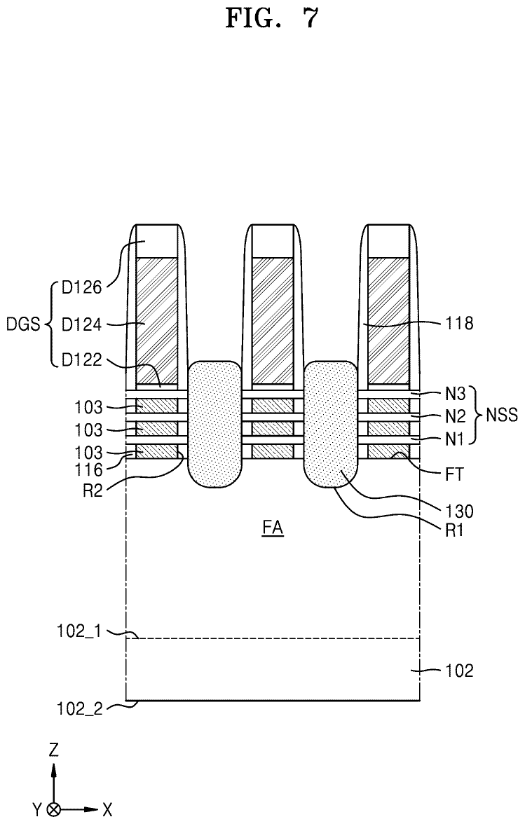

Referring to FIG. 7, a plurality of source/drain regions 130 may be formed in the inside of each of the plurality of first recesses R1. In some embodiments, in order to form the plurality of source/drain regions 130, a semiconductor substance may be subjected to epitaxial growth from a surface of the fin-shaped active region FA exposed on a bottom surface of each of the plurality of first recesses R1, a side wall of each of the first nanosheet N1, the second nanosheet N2, and the third nanosheet N3, which are included in the nanosheet stack NSS, and a side wall of each of the plurality of sacrificial semiconductor layers 103.

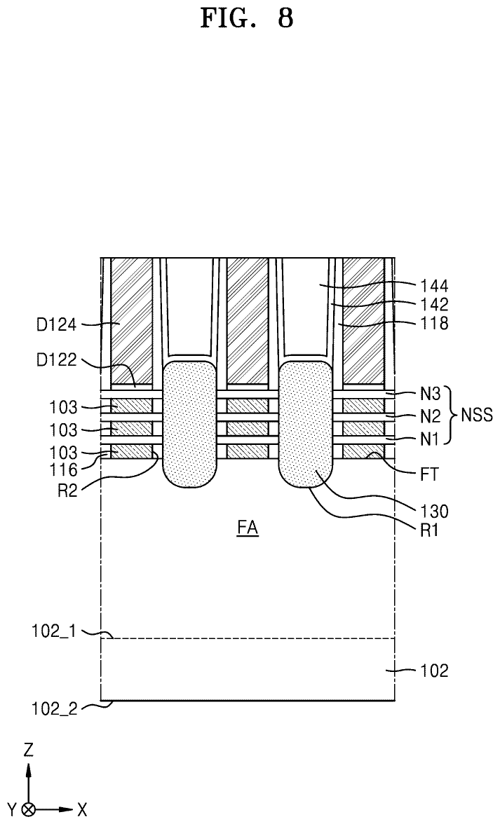

Referring to FIG. 8, after forming an insulating liner 142 covering a resultant product in FIG. 7, in which the plurality of source/drain regions 130 are formed, and forming an inter-gate insulating film 144 on the insulating liner 142, the insulating liner 142 and the inter-gate insulating film 144 are flattened, and thus the top surface of the capping layer D126 may be exposed.

Thereafter, the capping layer D126 is removed to expose the top surface of the dummy gate layer D124, and the insulating liner 142 and the inter-gate insulating film 144 may be partially removed so that the top surface of the inter-gate insulating film 144 and the top surface of the dummy gate layer D124 are at approximately the same level.

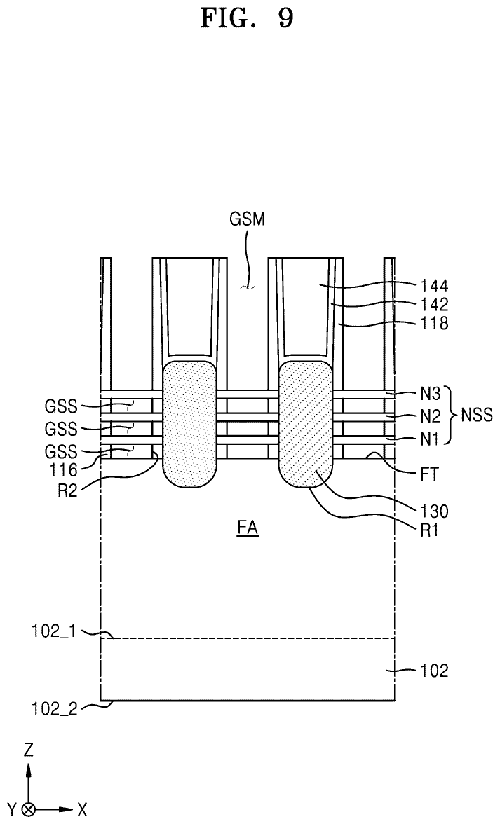

Referring to FIG. 9, the dummy gate layer D124 and the oxide film D122 below the dummy gate layer D124 may be removed to provide a main gate space GSM, and the plurality of nanosheet stacks NSS may be exposed through the main gate space GSM.

Next, the plurality of sacrificial semiconductor layers 103 remaining on the fin-shaped active region FA are removed through the main gate space GSM, and thus a sub-gate space GSS between each of the first nanosheet N1, the second nanosheet N2, and the third nanosheet N3, and between the first nanosheet N1 and the top surface of the fin may be provided.

In some embodiments, a difference in etching selectivity between the first nanosheet N1, the second nanosheet N2, and the third nanosheet N3 and the plurality of sacrificial semiconductor layers 103 may be utilized in order to selectively remove the plurality of sacrificial semiconductor layers 103.

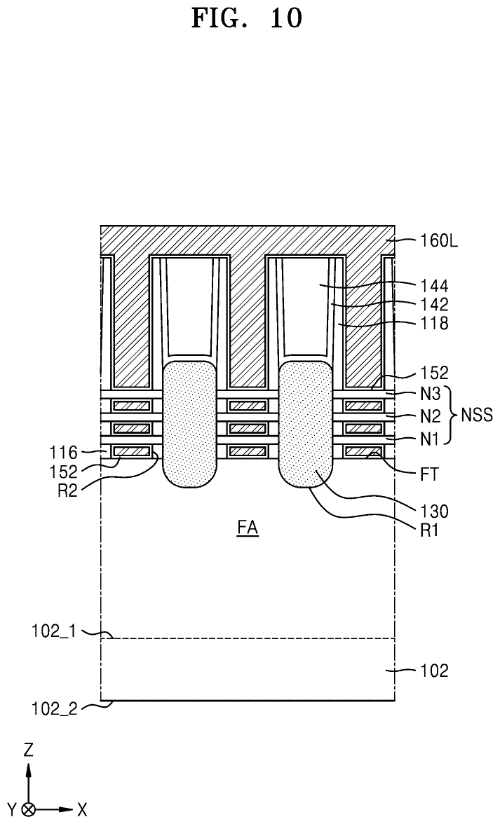

Referring to FIG. 10, a gate dielectric layer 152 may be formed within the main gate space GSM and the sub-gate space GSS. The gate dielectric layer 152 covering an exposed surface of the third nanosheet N3 may be formed in the main gate space GSM. The gate dielectric layer 152 that covers the plurality of nanosheets N1, N2, and N3 may be formed in the sub-gate space GSS. An atomic layer deposition (ALD) process may be used to form the gate dielectric layer 152.

Next, a conductive layer 160L for forming a gate, which covers the top surface of the inter-gate insulating film 144, while filling the main gate space GSM and the sub-gate space GSS, may be formed on the gate dielectric layer 152. The conductive layer 160L for forming a gate may include a metal, a metal nitride, a metal carbide, or a combination thereof. An ALD process or a chemical vapor deposition (CVD) process may be used to form the conductive layer 160L for forming a gate.

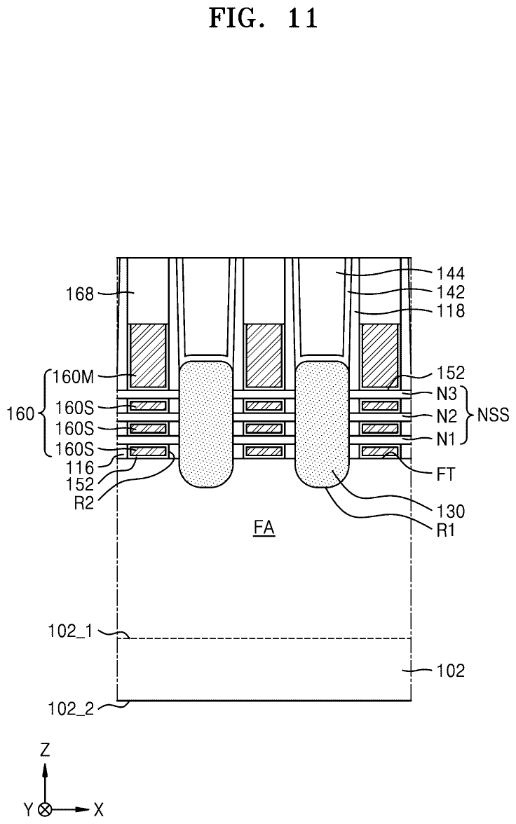

Referring to FIG. 11, a portion of the conductive layer 160L for forming a gate may be removed from the top surface thereof so that a top surface of the inter-gate insulating film 144 is exposed and a portion of an upper side of the main gate space GSM (see FIG. 9) is re-exposed. As a result, a plurality of gate lines 160 may be formed from the conductive layer 160L for forming a gate. Each of the plurality of gate lines 160 may include a main gate portion 160M and a plurality of sub-gate portions 160S.

In this case, in the main gate space GSM, the gate dielectric layer 152 and the outer insulating spacer 118 are also partially consumed from the respective upper sides thereof, and thus a height of each of the gate dielectric layer 152 and the outer insulating spacer 118 may be lowered. Thereafter, a capping insulating pattern 168 filling the main gate space GSM may be formed on the gate line 160.

An integrated circuit device 100 (see FIG. 12 and FIG. 13A to FIG. 13C) may be manufactured by the method (S10) of manufacturing an integrated circuit device, which is described with reference to FIG. 1 and FIG. 2 to FIG. 11. Hereinafter, the integrated circuit device 100 will be described with reference to FIG. 12 and FIG. 13A to FIG. 13C.

FIG. 12 is a planar layout diagram for describing the integrated circuit device 100 manufactured according to the method of manufacturing an integrated circuit device according to embodiments of the inventive concept. FIG. 13A to FIG. 13C are cross-sectional views for describing the integrated circuit device 100 manufactured according to the method of manufacturing an integrated circuit device according to embodiments of the inventive concept. Specifically, FIG. 13A is a cross-sectional view taken along line X1-X1 in FIG. 12. FIG. 13B is a cross-sectional view taken along line Y1-Y1 in FIG. 12. FIG. 13C is a cross-sectional view taken along line Y2-Y2 in FIG. 12.

The integrated circuit device 100 will be described with reference to FIG. 12 and FIG. 13A to FIG. 13C, wherein the integrated circuit device 100 includes a field effect transistor having a gate-all-around structure which includes an active region in a nanowire or nanosheet shape and includes a gate covering the active region.

The integrated circuit device 100 may include a substrate 102 having a first surface 102_1 and a second surface 102_2, and a plurality of fin-shaped active regions FA protruding in the first surface 102_1 of the substrate 102. The plurality of fin-shaped active regions FA may extend in a first horizontal direction (X direction) on the substrate 102 to be parallel to each other.

The substrate 102 may include a semiconductor such as Si or Ge, or a compound semiconductor such as SiGe, SiC, GaAs, InAs, InGaAs, or InP. The terms, used in the present specification, “SiGe”, “SiC”, “GaAs”, “InAs”, “InGaAs”, and “InP” mean materials containing the elements included in the respective terms but do not indicate chemical formulae representing stoichiometric relationships. The substrate 102 may include a conductive region, for example, a well doped with impurities, or a structure doped with impurities.

A device isolation film 112 may be disposed in a trench that defines the plurality of fin-shaped active regions FA. The device isolation film 112 may cover a portion of the side wall of each of the plurality of fin-shaped active regions FA and may be spaced apart from the substrate 102 in a vertical direction (Z direction). The device isolation film 112 may include a silicon oxide film. The device isolation film 112 may include a substance having etching selectivity different from that of the substrate 102.

As illustrated in FIG. 12, FIG. 13A, and FIG. 13C, the plurality of gate lines 160 may be disposed on the plurality of fin-shaped active regions FA. Each of the plurality of gate lines 160 may extend in a second horizontal direction (Y direction) intersecting the first horizontal direction (X direction). In regions in which the plurality of fin-shaped active regions FA and the plurality of gate lines 160 intersect, the plurality of nanosheet stacks NSS may be disposed on a top surface of each fin FT of each of the plurality of fin-shaped active regions FA. Each of the plurality of nanosheet stacks NSS may include at least one nanosheet facing the top surface of each fin FT of the fin-shaped active region FA at a location spaced apart from the top surface of each fin FT in the vertical direction (Z direction). The term “nanosheet” that is used in the present specification means a conductive structure having a cross-section that is substantially perpendicular to a direction in which current flows. The nanosheet should be understood to include a nanowire.

As illustrated in FIG. 13A and FIG. 13C, each of the plurality of nanosheet stacks NSS may include a first nanosheet N1, a second nanosheet N2, and a third nanosheet N3, which overlap each other in a mutually perpendicular direction (Z direction) in the fin-shaped active region FA. The first nanosheet N1, the second nanosheet N2, and the third nanosheet N3 may each have a different vertical distance (Z-direction distance) from the top surface of each fin FT of the fin-shaped active region FA. Each of the plurality of gate lines 160 may cover the first nanosheet N1, the second nanosheet N2, and the third nanosheet N3, which are included in a nanosheet stack NSS and overlap each other in the vertical direction (Z direction).

FIG. 12 exemplifies a case where a planar shape of the nanosheet stack NSS is approximately square, but the planar shape of the nanosheet stack NSS is not limited thereto. The nanosheet stack NSS may have various planar shapes depending on the planar shape of each of the fin-shaped active region FA and the gate line 160. In the present embodiment, a configuration has been exemplified, wherein the plurality of nanosheet stacks NSS and the plurality of gate lines 160 are disposed on one fin-shaped active region FA, and the plurality of nanosheet stacks NSS are disposed in a row along the first horizontal direction (X direction) on one single fin-shaped active region FA. However, each of the numbers of nanosheet stacks NSS and gate lines 160, which are disposed on one fin-shaped active region FA, is not particularly limited.

Each of the first nanosheet N1, the second nanosheet N2, and the third nanosheet N3, which are included in the nanosheet stack NSS, may function as a channel region. In embodiments, each of the first nanosheet N1, the second nanosheet N2, and the third nanosheet N3 may have a thickness selected within a range of about 4 nm to about 6 nm, but the thickness thereof is not limited thereto. Here, each thickness of the first nanosheet N1, the second nanosheet N2, and the third nanosheet N3 refers to the size along the vertical direction (Z direction). In embodiments, the first nanosheet N1, the second nanosheet N2, and the third nanosheet N3 may have substantially the same thickness along the vertical direction (Z direction). In other exemplary embodiments, at least a portion of the first nanosheet N1, the second nanosheet N2, or the third nanosheet N3 may have thicknesses different from each other along the vertical direction (Z direction). In embodiments, each of the first nanosheet N1, the second nanosheet N2, and the third nanosheet N3, which are included in the nanosheet stack NSS, may include a Si layer, a SiGe layer, or a combination thereof.

As exemplified in FIG. 13A, the first nanosheet N1, the second nanosheet N2, and the third nanosheet N3, which are included in one nanosheet stack NSS, may have the same or similar sizes in the first horizontal direction (X direction). In other embodiments, unlike exemplified in FIG. 13A, at least one selected from the first nanosheet N1, the second nanosheet N2, or the third nanosheet N3, which are included in one nanosheet stack NSS, may have a different size from each other in the first horizontal direction (X direction). In the present embodiment, a case where each of the plurality of nanosheet stacks NSS includes three nanosheets has been exemplified, but an embodiment of the inventive concept is not limited thereto. For example, the nanosheet stack NSS may include at least one nanosheet, and the number of nanosheets constituting the nanosheet stack NSS is not particularly limited.

As exemplified in FIG. 13A and FIG. 13C, each of the plurality of gate lines 160 may include a main gate portion 160M and a plurality of sub-gate portions 160S. The main gate portion 160M may cover the top surface of the nanosheet stack NSS and may extend in the second horizontal direction (Y direction). The plurality of the sub-gate portions 160S may be integrally connected to the main gate portion 160M and may be each arranged one by one between each of the first nanosheet N1, the second nanosheet N2, and the third nanosheet N3, as well as between the first nanosheet N1 and the fin-shaped active region FA. In the vertical direction (Z direction), a thickness of each of the plurality of sub-gate portions 160S may be less than a thickness of the main gate portion 160M.

Each of the plurality of gate lines 160 may include a metal, a metal nitride, a metal carbide, or a combination thereof. The above-described metal may be selected from Ti, W, Ru, Nb, Mo, Hf, Ni, Co, Pt, Yb, Tb, Dy, Er, and Pd. The above-described metal nitride may be selected from TiN and TaN. The above-described metal carbide may be TiAlC. However, the substance constituting the plurality of gate lines 160 is not limited to those exemplified above.

As exemplified in FIG. 13A and FIG. 13B, the plurality of first recesses R1 may be formed in the fin-shaped active region FA. A vertical level of the lowest surface of each of the plurality of first recesses R1 may be lower than a vertical level of the top surface of each fin FT of the fin-shaped active region FA.

As exemplified in FIG. 13A and FIG. 13B, the plurality of source/drain regions 130 may be disposed within the plurality of first recesses R1. Each of the plurality of source/drain regions 130 may be arranged at a location adjacent to at least one gate line 160 selected from among the plurality of gate lines 160. Each of the plurality of source/drain regions 130 may have surfaces facing the first nanosheet N1, the second nanosheet N2, and the third nanosheet N3, which are included in the adjacent nanosheet stack NSS. Each of the plurality of source/drain regions 130 may be in contact with the first nanosheet N1, the second nanosheet N2, and the third nanosheet N3, which are included in the adjacent nanosheet stack NSS.

A gate dielectric layer 152 may be between the nanosheet stack NSS and the gate line 160. In embodiments, the gate dielectric layer 152 may include a laminated structure of an interfacial dielectric layer and a high dielectric layer. The interfacial dielectric layer may include a low dielectric substance film having a dielectric constant of about 9 or less such as a silicon oxide film, a silicon oxynitride film, or a combination thereof. In embodiments, the interfacial dielectric layer may be omitted. The high dielectric layer may include a substance having a dielectric constant higher than the dielectric constant of the silicon oxide film. For example, the high dielectric layer may have a dielectric constant of about 10 to about 25. The high dielectric layer may include hafnium oxide but is not limited thereto.

As exemplified in FIG. 13A, a plurality of second recesses R2 may be formed between each of the plurality of the sub-gate portions 160S adjacent to the source/drain region 130.

As exemplified in FIG. 13A, a plurality of inner insulating spacers 116 may be arranged within the plurality of second recesses R2. The inner insulating spacer 116 may be disposed between adjacent nanosheets, for example, between the first nanosheet N1 and the second nanosheet N2 and between the second nanosheet N2 and the third nanosheet N3. The inner insulating spacer 116 may be disposed between the gate dielectric layer 152 and the source/drain region 130.

The inner insulating spacer 116 may include a silicon nitride, a silicon oxide, SiCN, SiBN, SiON, SiOCN, SiBCN, SiOC, or a combination thereof.

As exemplified in FIG. 13A and FIG. 13C, each top surface of the gate dielectric layer 152 and the gate line 160 may be covered with a capping insulating pattern 168. The capping insulating pattern 168 may include a silicon nitride film.

Both side walls of each of the gate line 160 and the capping insulating pattern 168 may be covered with an outer insulating spacer 118. The outer insulating spacer 118 may cover both side walls of the main gate portion 160M on the top surface of the plurality of nanosheet stacks NSS. The outer insulating spacer 118 may be spaced apart from the gate line 160 with the gate dielectric layer 152 therebetween.

As exemplified in FIGS. 13A and 13B, a plurality of recess-side insulating spacers 119 that cover the side walls of the source/drain region 130 may be disposed on a top surface of the device isolation film 112. In embodiments, each of the plurality of recess-side insulating spacers 119 may be integrally connected to the outer insulating spacer 118 adjacent thereto.

Each of the plurality of outer insulating spacers 118 and the plurality of recess-side insulating spacers 119 may each include a silicon nitride, a silicon oxide, SiCN, SiBN, SiON, SiOCN, SiBCN, SiOC, or a combination thereof. The terms “SiCN”, “SiBN”, “SiON”, “SiOCN”, “SiBCN”, and “SiOC”, used in the present specification, mean materials containing elements, which are contained in the respective terms, but “SiCN”, “SiBN”, “SiON”, “SiOCN”, “SiBCN”, and “SiOC” are not chemical formulae representing stoichiometric relationships.

A first metal silicide film 172 may be formed on the top surface of each of the plurality of source/drain regions 130. The first metal silicide film 172 may include a metal containing Ti, W, Ru, Nb, Mo, Hf, Ni, Co, Pt, Yb, Tb, Dy, Er, or Pd. For example, the first metal silicide film 172 may include titanium silicide, but is not limited thereto.

On the substrate 102, the plurality of source/drain regions 130, the plurality of the first metal silicide films 172, and the plurality of outer insulating spacers 118 may be covered with the insulating liner 142. In embodiments, the insulating liner 142 may be omitted. The inter-gate insulating film 144 may be disposed on the insulating liner 142. When the insulating liner 142 is omitted, the inter-gate insulating film 144 may be in contact with the plurality of source/drain regions 130.

The insulating liner 142 and the inter-gate insulating film 144 may be sequentially disposed on the plurality of source/drain regions 130 and the plurality of first metal silicide films 172. The insulating liner 142 and the inter-gate insulating film 144 may constitute an insulating structure. In embodiments, the insulating liner 142 may include a silicon nitride, SiCN, SiBN, SiON, SiOCN, SiBCN, or a combination thereof but is not limited thereto. The inter-gate insulating film 144 may include a silicon oxide film but is not limited thereto.

Both side walls of each of the plurality of sub-gate portions 160S included in the plurality of gate lines 160 may be spaced apart from the source/drain region 130 with the gate dielectric layer 152 therebetween. The gate dielectric layer 152 may be between the sub-gate portion 160S included in the gate line 160 and each of the first nanosheet N1, the second nanosheet N2, and the third nanosheet N3, and between the sub-gate portion 160S included in the gate line 160 and the source/drain region 130.

The plurality of nanosheet stacks NSS is disposed on the top surface of each fin FT of each of the plurality of fin-shaped active regions FA in regions in which the plurality of fin-shaped active regions FA and the plurality of gate lines 160 intersect and may face the top surface of each fin FT of the fin-shaped active region FA at a location spaced apart from the fin-shaped active regions FA. A plurality of nanosheet transistors may be formed at portions where the plurality of fin-shaped active regions FA and the plurality of gate lines 160 intersect on the substrate 102.

As exemplified in FIG. 13A and FIG. 13B, an active contact CA may be disposed on the source/drain region 130. Each of the active contacts CA may penetrate the inter-gate insulating film 144 and the insulating liner 142 in the vertical direction (Z direction), thereby being in contact with the first metal silicide film 172. Each of the active contacts CA may be electrically connected to the source/drain regions 130 through the first metal silicide film 172.

The active contact CA may include a conductive barrier pattern 174 and a contact plug 176, which are sequentially laminated on the source/drain region 130. The conductive barrier pattern 174 covers a bottom surface and side walls of the contact plug 176 and may be in contact with a bottom surface and side walls of the contact plug 176. The active contact CA may extend in the vertical direction (Z direction) through the inter-gate insulating film 144 and the insulating liner 142. The conductive barrier pattern 174 may be between the first metal silicide film 172 and the contact plug 176. The conductive barrier pattern 174 may have a surface that is in contact with the first metal silicide film 172 and a surface that is in contact with the contact plug 176. In embodiments, the conductive barrier pattern 174 may include a metal or a metal nitride. For example, the conductive barrier pattern 174 may include Ti, Ta, W, TiN, TaN, WN, WCN, TiSiN, TaSiN, WSiN, or a combination thereof but is not limited thereto. The contact plug 176 may include molybdenum (Mo), copper (Cu), tungsten (W), cobalt (Co), ruthenium (Ru), manganese (Mn), titanium (Ti), tantalum (Ta), aluminum (Al), a combination thereof, or an alloy thereof, but is not limited thereto.

As exemplified in FIG. 13A to FIG. 13C, each top surface of the active contact CA, the capping insulating pattern 168, and the inter-gate insulating film 144 may be covered with an upper insulating structure 180. The upper insulating structure 180 may include an etch stop film 182 and an interlayer insulating film 184, which are sequentially laminated on each of the active contact CA, a plurality of the capping insulating patterns 168, and the inter-gate insulating film 144. The etch stop film 182 may include silicon carbide (SiC), a silicon nitride (SiN), a nitrogen-doped silicon carbide (SiC:N), SiOC, AlN, AlON, AlO, AlOC, or a combination thereof. The interlayer insulating film 184 may include an oxide film, a nitride film, an ultra low-k (ULK) film having an ultra low dielectric constant K of about 2.2 to about 2.4, or a combination thereof. For example, the interlayer insulating film 184 may include a tetraethylorthosilicate (TEOS) film, a high density plasma (HDP) oxide film, a boro-phospho-silicate glass (BPSG) film, a flowable chemical vapor deposition (FCVD) oxide film, a SiON film, a SiN film, a SiOC film, a SiCOH film, or a combination thereof but is not limited thereto.

As exemplified in FIG. 13A and FIG. 13B, a via contact VA may be disposed on the active contact CA. Each of the via contacts VA may penetrate the upper insulating structure 180, thereby being in contact with the active contact CA. Each of the source/drain regions 130 may be electrically connected to the via contact VA through the first metal silicide film 172 and the active contact CA. The bottom surface of each via contact VA may be in contact with the top surface of the active contact CA. The via contact VA may include tungsten (W), molybdenum (Mo), and/or ruthenium (Ru), but is not limited thereto.

The wiring line M1 as exemplified in FIG. 13A and FIG. 13B may be disposed to penetrate the upper insulating film 192. The wiring line M1 may be connected to the via contact VA located below. In some embodiments, the wiring line M1 may extend in the first horizontal direction (X direction). The wiring line M1 may include molybdenum (Mo), copper (Cu), tungsten (W), cobalt (Co), ruthenium (Ru), manganese (Mn), titanium (Ti), tantalum (Ta), aluminum (Al), a combination thereof, or an alloy thereof but is not limited thereto.

Since performance and reliability of the method (S10) of manufacturing an integrated circuit device using the etchant composition according to embodiments of the inventive concept are improved, performance and reliability of the integrated circuit device 100 manufactured by the method may be improved.

While the inventive concept has been particularly shown and described with reference to embodiments thereof, it will be understood that various changes in form and details may be made therein without departing from the spirit and scope of the following claims.

What is claimed is:

1. An etchant composition for etching a silicon germanium film, the etchant composition comprising:
about 3 wt % to about 90 wt % of an oxidizing agent based on a total amount of the etchant composition;
about 0.01 wt % to about 5 wt % of a fluorine compound based on the total amount of the etchant composition;
about 0.01 wt % to about 5 wt % of an amine compound based on the total amount of the etchant composition;
about 0.01 wt % to about 1 wt % of an inhibitor based on the total amount of the etchant composition;
about 1.5 wt % to about 88.5 wt % of an organic solvent based on the total amount of the etchant composition; and
a residual amount of water.

2. The etchant composition of claim 1, wherein the oxidizing agent comprises a peroxyacid compound having 2 to 4 carbon atoms or a combination thereof.

3. The etchant composition of claim 1, wherein the fluorine compound comprises hydrofluoric acid (HF), lithium fluoride (LiF), sodium fluoride (NaF), potassium fluoride (KF), aluminum fluoride (AlF₃), lithium borofluoride (LiBF₄), calcium fluoride (CaF₂), sodium bifluoride (NaHF₂), ammonium fluoride (NH₄F), ammonium difluoride (NH₄HF₂), tetramethylammonium fluoride ((CH₃)₄NF), potassium bifluoride (KHF₂), fluoroboric acid (HBF₄), ammonium borofluoride (NH₄BF₄), potassium borofluoride (KBF₄), hexafluorosilicic acid (H₂SiF₆), or a combination thereof.

4. The etchant composition of claim 1, wherein the amine compound comprises an aliphatic diamine compound having 1 to 12 carbon atoms, a methylated aliphatic diamine compound having 1 to 12 carbon atoms, or a combination thereof.

5. The etchant composition of claim 1, wherein the organic solvent comprises a carboxylic acid compound having 2 to 4 carbon atoms, or a combination thereof.

6. The etchant composition of claim 1, wherein the oxidizing agent has the same number of carbon atoms as the number of carbon atoms of the organic solvent.

7. The etchant composition of claim 6, wherein the oxidizing agent and the organic solvent respectively comprise: peracetic acid and acetic acid; perpropionic acid and propionic acid; or perbutyric acid and butyric acid.

8. The etchant composition of claim 1, wherein the inhibitor comprises sulfuric acid or methanesulfonic acid.

9. A method of manufacturing an integrated circuit device, the method comprising:
forming a laminated structure in which a plurality of silicon films and a plurality of silicon germanium films are alternately laminated one by one on a substrate;
etching a portion of the laminated structure to form a recess that exposes the plurality of silicon films and the plurality of silicon germanium films; and
selectively removing, by using an etchant composition, the plurality of silicon germanium films among the plurality of silicon films and the plurality of silicon germanium films, which are exposed by the recess,
wherein the etchant composition comprises:
about 3 wt % to about 90 wt % of an oxidizing agent based on a total amount of the etchant composition;
about 0.01 wt % to about 5 wt % of a fluorine compound based on the total amount of the etchant composition;
about 0.01 wt % to about 5 wt % of an amine compound based on the total amount of the etchant composition;
about 0.01 wt % to about 1 wt % of an inhibitor based on the total amount of the etchant composition;
about 1.5 wt % to about 88.5 wt % of an organic solvent based on the total amount of the etchant composition; and
a residual amount of water.

10. The method of claim 9, further comprising forming a dummy gate structure on the laminated structure and an outer insulating spacer on both side walls of the dummy gate structure,
wherein the dummy gate structure and the outer insulating spacer are used as an etching mask in the forming of the recess.

11. The method of claim 9,
wherein, during the selective removing of the plurality of silicon germanium films,
a portion of each of the plurality of silicon germanium films is removed, but at least one other portion of each of the plurality of silicon germanium films is not removed.

12. The method of claim 9, wherein the oxidizing agent comprises a peroxyacid compound having 2 to 4 carbon atoms, or a combination thereof.

13. The method of claim 9, wherein the fluorine compound comprises hydrofluoric acid (HF), lithium fluoride (LiF), sodium fluoride (NaF), potassium fluoride (KF), aluminum fluoride (AlF₃), lithium borofluoride (LiBF₄), calcium fluoride (CaF₂), sodium bifluoride (NaHF₂), ammonium fluoride (NH₄F), ammonium difluoride (NH₄HF₂), tetramethylammonium fluoride ((CH₃)₄NF), potassium bifluoride (KHF₂), fluoroboric acid (HBF₄), ammonium borofluoride (NH₄BF₄), potassium borofluoride (KBF₄), hexafluorosilicic acid (H₂SiF₆), or a combination thereof.

14. The method of claim 9, wherein the amine compound comprises an aliphatic diamine compound having 1 to 12 carbon atoms, a methylated aliphatic diamine compound having 1 to 12 carbon atoms, or a combination thereof.

15. The method of claim 9, wherein the organic solvent comprises a carboxylic acid compound having 2 to 4 carbon atoms or a combination thereof.

16. The method of claim 9, wherein the oxidizing agent and the organic solvent respectively comprise: peracetic acid and acetic acid; perpropionic acid and propionic acid; or perbutyric acid and butyric acid.

17. The method of claim 9, wherein the inhibitor comprises sulfuric acid or methanesulfonic acid.

18. A method of manufacturing an integrated circuit device, the method comprising:
forming a laminated structure in which a plurality of silicon films and a plurality of silicon germanium films are alternately laminated one by one on a substrate;
forming a dummy gate structure on the laminated structure;
etching a portion of the dummy gate structure by using the dummy gate structure as an etching mask to thereby form a source/drain recess exposing the plurality of silicon films and the plurality of silicon germanium films;
selectively removing, by using an etchant composition, a portion of each of the plurality of silicon germanium films among the plurality of silicon films and the plurality of silicon germanium films, which are exposed by the source/drain recess, to thereby form a plurality of inner recesses;
forming a plurality of inner spacers within each of the plurality of inner recesses;
forming a source/drain region within the source/drain recess; and
removing the plurality of silicon germanium films and forming a plurality of gate electrodes,
wherein the etchant composition comprises:
about 3 wt % to about 90 wt % of an oxidizing agent based on the total amount of the etchant composition;
about 0.01 wt % to about 5 wt % of a fluorine compound based on the total amount of the etchant composition;
about 0.01 wt % to about 5 wt % of an amine compound based on the total amount of the etchant composition;
about 0.01 wt % to about 1 wt % of an inhibitor based on the total amount of the etchant composition;
about 1.5 wt % to about 88.5 wt % of an organic solvent based on the total amount of the etchant composition; and
a residual amount of water.

19. The method of claim 18, wherein each of the plurality of inner spacers comprises silicon nitride.

20. The method of claim 18,
wherein the oxidizing agent and the organic solvent respectively comprise: peracetic acid and acetic acid; perpropionic acid and propionic acid; or perbutyric acid and butyric acid, and
the inhibitor comprises sulfuric acid or methanesulfonic acid.
